(19) United States
(12) Patent Application Publication
(10) Pub. No.: US 2019/0326464 A1
(43) Pub. Date: Oct. 24, 2019

(54) THREE LAYER PHOTOLITHOGRAPHY

(71) Applicant: Advanced Research Corporation, White Bear Lake, MN (US)

(72) Inventors: Greg Wagner, Santa Fe, NM (US); Joe Tersteeg, Minneapolis, MN (US)

(21) Appl. No.: 16/393,954

(22) Filed: Apr. 24, 2019

Related U.S. Application Data
(60) Provisional application No. 62/661,918, filed on Apr. 24, 2018.
(60) Provisional application No. 62/749,214, filed on Oct. 23, 2018.

(51) Int. Cl. H01L 31/118; H01L 31/02; H01L 31/18

(52) U.S. Cl. CPC H01L 31/118; H01L 31/186; H01L 31/02005

(57) ABSTRACT

Various methods and systems are provided for three layer photolithography. In one embodiment, a process includes disposing a radiation hard dielectric layer on a substrate, the radiation hard dielectric layer comprising a dielectric that maintains defined dielectric properties when exposed to at least 50 mrads of proton radiation and/or at least 4×10¹⁵ of 1 MeV equivalent neutron radiation; patterning the radiation hard dielectric layer; and treating the radiation hard dielectric layer. In one embodiment, a device includes a substrate and a patterned radiation hard dielectric layer disposed on the substrate, the radiation hard dielectric layer comprising a dielectric that maintains defined dielectric properties when exposed to at least 50 mrads of proton radiation and/or at least 4×10¹⁵ of 1 MeV equivalent neutron radiation.

### CROSS REFERENCE TO RELATED APPLICATIONS

This application claims priority to, and the benefit of, co-pending U.S. provisional application entitled “THREE LAYER PHOTOLITHOGRAPHY” having Ser. No. 62/661,918, filed Apr. 24, 2018 and co-pending U.S. provisional application entitled “THREE LAYER PHOTOLITHOGRAPHY” having Ser. No. 62/749,214, filed Oct. 23, 2018, the entireties of which are hereby incorporated by reference.

### BACKGROUND

The High Energy Physics (HEP) community has been involved in the development of highly segmented and miniaturized detection elements ever since silicon strip detectors were first invented in the late 1970s. Various experiments have employed silicon detectors in a variety of readout configurations such as silicon drift detectors, charge-coupled devices, hybrid pixel detectors, silicon-based calorimeters and even trackers in satellites. Continued expansion in scale, density, complexity, and radiation hardness of silicon-based detectors for the HEP community needs concurrent development of technologies that enable interconnections between detector elements, readout electronics and data acquisition systems.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1A is a substrate with patterned material, in accordance with various embodiment of the present disclosure.

FIG. 1B is a cross section of substrate with patterned material, in accordance with various embodiment of the present disclosure.

FIG. 2A is a substrate with three patterned material layers, in accordance with various embodiment of the present disclosure.

FIG. 2B is a cross section of substrate with three patterned material layers, in accordance with various embodiment of the present disclosure.

FIG. 3A is a substrate with three patterned material layers and bump metal deposited, in accordance with various embodiment of the present disclosure.

FIG. 3B is a cross section of substrate with three patterned material layers and bump metal deposited, in accordance with various embodiment of the present disclosure.

FIG. 4A is a SEM cross section of realized 3 layer patterned material with Bump Metal deposited, in accordance with various embodiment of the present disclosure.

FIG. 4B is a model of cross section of substrate with three patterned material layers and bump metal deposited, in accordance with various embodiment of the present disclosure.

FIG. 5A is a model showing Bump Metal embedded in a dielectric material, in accordance with various embodiment of the present disclosure.

FIG. 5B is a cross section of model showing Bump Metal embedded in a dielectric material, in accordance with various embodiment of the present disclosure.

FIG. 6 is a SEM image of a realized, successful 3 layer patterned material development showing Indium bumps with a Polyimide base layer, in accordance with various embodiment of the present disclosure.

FIG. 7 is a cross-section of model depicting a 2 layer lithographic process, in accordance with various embodiment of the present disclosure.

FIG. 8 is a cross-section of model depicting a 2 layer lithographic process with metal deposited on structure, in accordance with various embodiment of the present disclosure.

### DETAILED DESCRIPTION

Disclosed herein are various embodiments of methods related to three layer photolithography. Reference will now be made in detail to the description of the embodiments as illustrated in the drawings, wherein like reference numbers indicate like parts throughout the several views.

Current and future generations of pixelated silicon-based detectors for HEP comprises a silicon detection-element bonded to a Read-Out Integrated Circuit (ROIC). The ROIC is bonded and/or attached to the detection-element to measure the electrical signal in the detection-element as well as providing electrical routing and control functions.

The pixilated detection-element/ROIC interconnect issues present in future generations of HEP detectors presents a unique set of challenges including bump pitch, detection-element to ROIC spacing and the ability to maintain several hundred volts between the detection-element and ROIC without electrical breakdown. The criterial of maintaining the necessary voltage without electrical breakdown can be accomplished by incorporating a dielectric material between the detection-element and ROIC. One significant issue is that these criteria must be met in a high radiation environment. Dielectric materials, when exposed to high levels of ionizing radiation including charge events (proton and electron interaction), neutral events (neutron interaction) as well as photon events (optical to gamma ray energies), can undergo material changes which degrade the desired properties such as Dielectric Constant and Breakdown Voltage. The degradation of these material properties can render the material ineffective to its intended application under operational and usage conditions.

The criteria of maintaining high breakdown voltages in high radiation environments needs the development of bumping and interconnect manufacturing process using dielectric materials that can withstand high levels of proton, neutron and gamma radiation while maintaining sufficient dielectric properties. One need in the future generations of HEP detectors is the development of a processing capability to incorporate dielectric materials which can survive these radiation environments into a standard style interconnect processing capability. One such solution is presented here.

Three Layer Patterning Process

One method to address these issues is a three layer photolithography and/or patterning process for the manufacture of interconnects. The three layer patterning process is significant as it is highly economical and scalable to the dimensions needed for future generations of detectors. This process is desirable as it represents a single process step perturbation to standard processing sequences and hence has robust manufacturability.

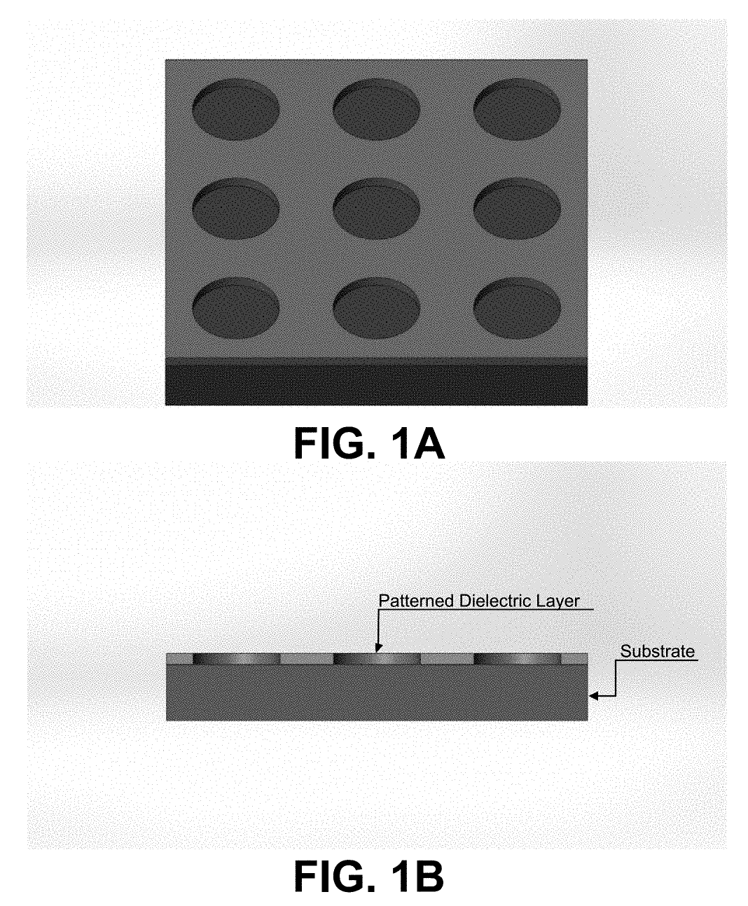

The subsequent figures depict one method of a three layer patterning process. First, a radiation hard dielectric, such as polyimide, is spun on the appropriate substrate and patterned to the appropriate dimensions as shown in FIGS. 1A and 1B. The material is then processed such that it is capable of surviving subsequent processing of material layers and steps. This subsequent processing may be thermal, chemical or plasma based. This substrate could be either the detector wafer, ROIC wafer, a material used as an interposer or a combination thereof. The patterning method will depend on the specific material and may include standard patterning techniques such as exposure to light, wet etching, dry etching or solvent patterning methods. The desired thickness of this layer may be 4-6 um or any appropriate thickness.

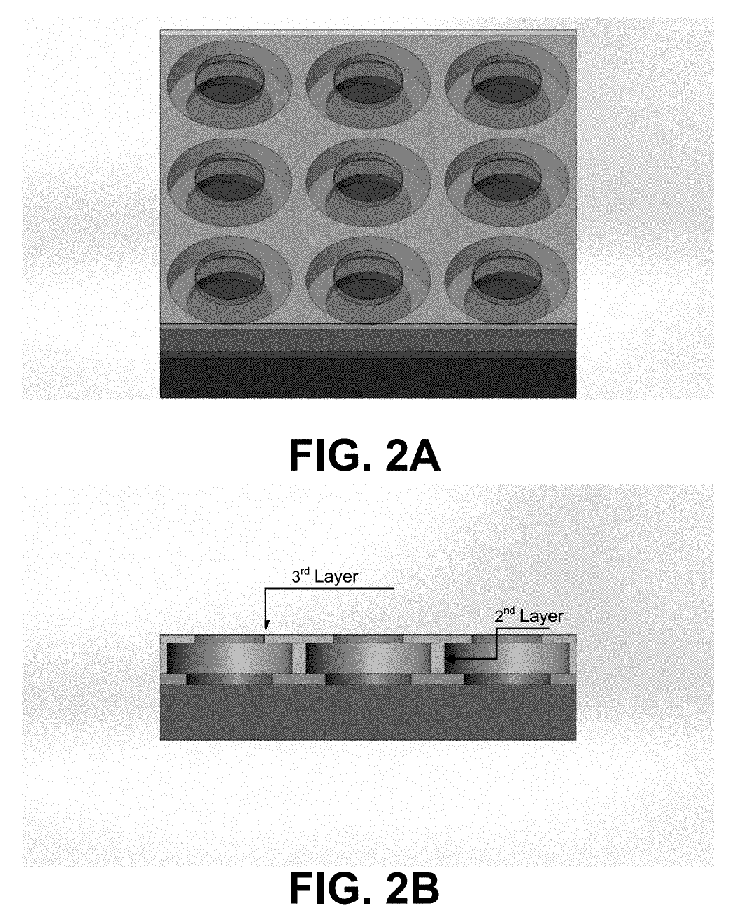

Next, FIGS. 2A and 2B, two layers of photoresist are applied to comprise layers 2 and 3. Layer 2 photoresist, which may be a standard Lift-Off photoresist, is applied to the substrate and the photoresist is exposed so that it will develop away during final processing. The rate of development will depend on the cure conditions which the resist was exposed to during processing. The goal thickness of this layer may be 10-11 um or any appropriate thickness. After an appropriate “soft cure”, the third layer of resist may be spun on the wafer and the ensemble subjected to an additional “soft cure”. The ensemble, consisting of all three layers, may then be patterned using standard processing techniques using a mask with features which may have dimensions slightly smaller than the dimensions of the first (dielectric) layer. This resulting structure may then be placed in an appropriate chemical developer and the exposed materials removed as depicted in FIGS. 2A and 2B. The desired thickness of the third layer may be 2-6 um or any appropriate thickness. The patterning method will depend on the specific material and may include standard patterning techniques such as exposure to light, wet etching, dry etching or solvent patterning methods.

The result of this process can be seen in FIG. 2B. The hole in the top most photoresist layer may be slightly smaller than in the bottom most layer (dielectric). The thick photoresist (2nd layer) in the center of the sandwich has been developed sufficiently wider than the upper and lower material layers.

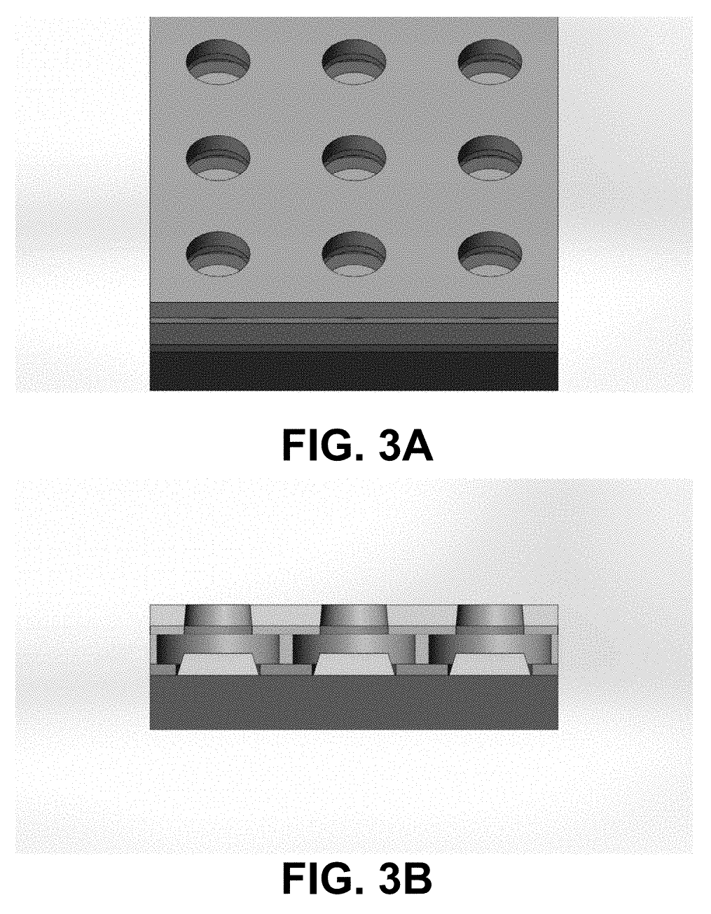

Next, a Bump Metal is deposited onto the resist stack. The Bump Metal may be Indium or any appropriate metal. The deposition method may be evaporation or any appropriate method. The top layer provides sufficient masking so that the Bump Metal is principally deposited into the dielectric well formed in the first layer of patterned material. The resist in the center is clear of the deposition area but provides sufficient mechanical integrity to support the top resist. This is shown in FIGS. 3A and 3B.

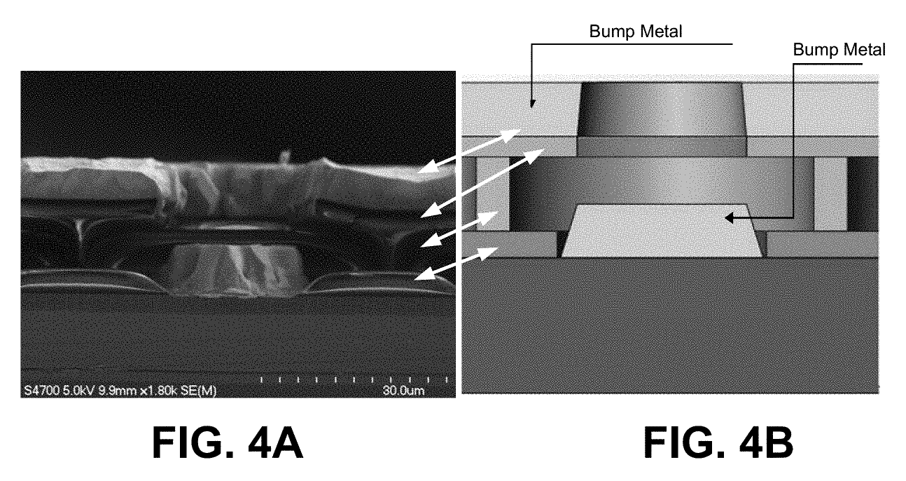

The realization of this process is shown in FIG. 4A with the model shown in FIG. 4B for reference. On the left (4A) is a cross-section of a wafer processed to this point with the 3-layer process. On the right (4B) hand side is a zoom-in of the model shown in FIG. 3B. On the processed wafer (4A), the first layer (dielectric) was 4.2 um thick Polyimide, the Bump Metal was Indium and was 8.2 um tall and 25 um wide at its base. The 2nd and 3rd layers where standard photoresists used in deposition lift-off processing techniques.

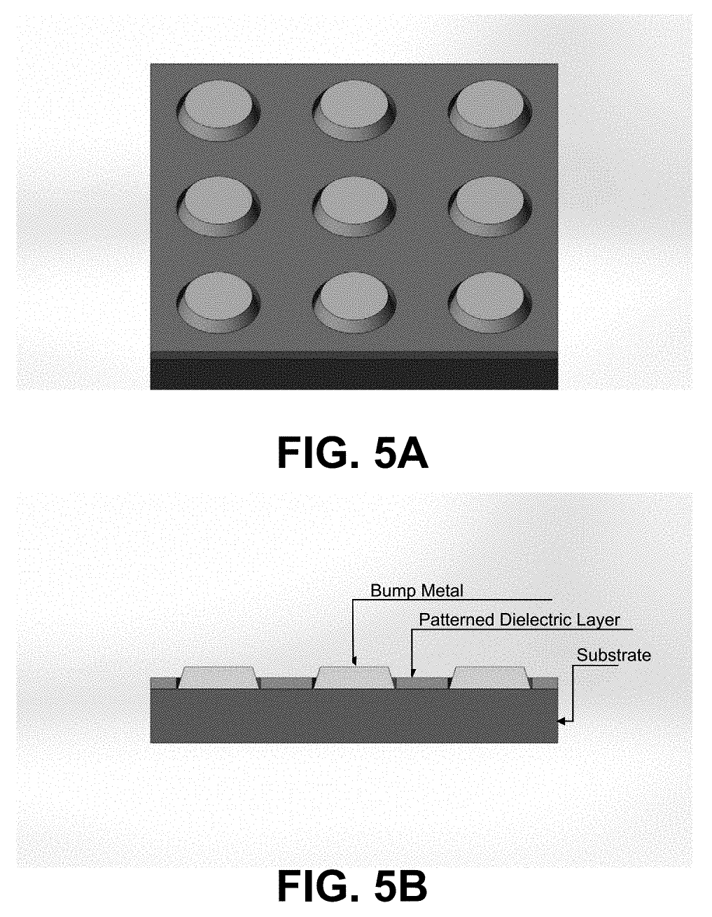

The final step of the process is to remove the patterned layers 2 and 3. This removal may be done using any appropriate method such as chemical, plasma or other appropriate method. This step removes the 2nd and 3rd patterned layers and “lifts off” the deposition materials on the top of the photoresist leaving only the radiation hard dielectric with the protruding embedded Bump Metal. This is show in FIGS. 5A and 5B.

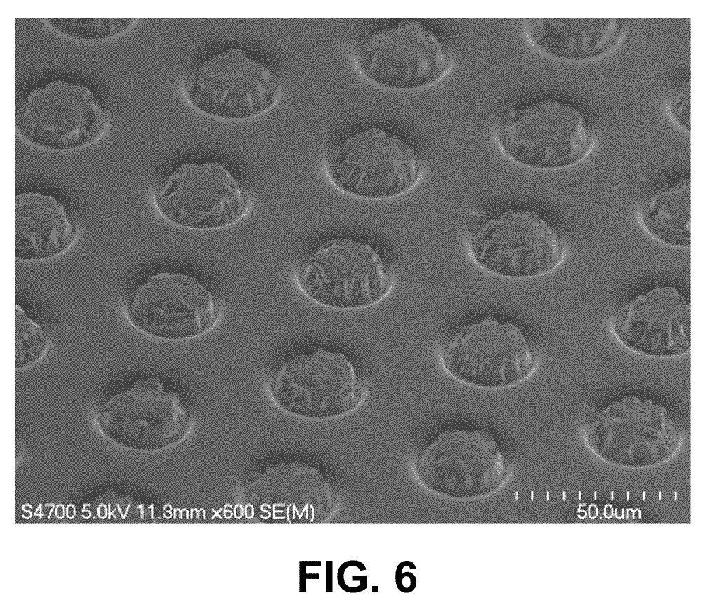

FIG. 6 is an SEM image of a realized process after the final step shown in FIGS. 5A and 5B. Here, the surface was coated with 2000 A of Cr to allow for SEM imaging as the charging effects of the dielectric rendered the image difficult to understand. The wafer and material parameters where similar to those described in FIG. 4A.

In addition to providing electrical isolation in the interconnect region, the radiation hard dielectric materials may be applied, using appropriate coating techniques, to regions outside the bumping region for the same purpose. The materials selected for this application may be used to provide electrical isolation in regions where the surface voltage on one of the chips, either sensor or ROIC, is high and susceptibility to electrical discharges exist. This includes regions utilized for high voltage distribution. The material may be applied to the sensor, ROIC, an interposer or a combination thereof.

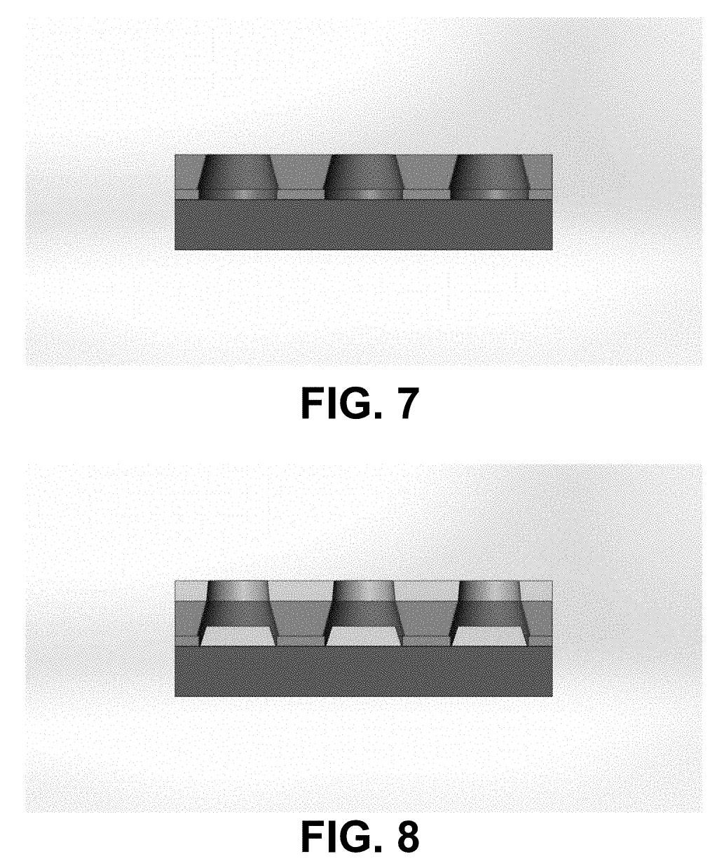

FIGS. 7 and 8 illustrate another implementation of the lithography process that can be used to produce the structure(s). Here, the later 2 layers of photoresist are replaced with a single layer of photoresist that has a significant angle to the resist profile. This profile can be achieved with special processing of the photoresist and serves the purposes of defining the viewable deposition area and preventing the metallic material from depositing on the sidewalls of the resist. The final step of the process is to remove the patterned layers, leaving the bump metal and radiation hard dielectric.

FIG. 7 shows the single layer of angled photoresist on top of the layer of radiation hard dielectric. FIG. 8 shows the deposition of the metal on top of the photoresist layer, and the deposition of the bump metal on the substrate. These figures illustrate an alternate process approach and can replace the steps shown in FIGS. 2A-2B and FIGS. 3A-3B.

In some embodiments, disclosed is a coatable, radiation tolerant dielectric material for electrical isolation in the assembly of sensors used in particle physics experiments. Materials of the radiation tolerant dielectric material can be: a polyimide or derivative, a benzocyclobutene or derivative, an SU-8 or derivative, a poly(p-xylylene) or derivative.

In some embodiments, disclosed is a three layer electrical interconnect patterning process which incorporates a radiation tolerant dielectric as the first layer. In some aspects an application can be in high radiation environments. Materials of the radiation tolerant dielectric material can be: a polyimide or derivative, a benzocyclobutene or derivative, an SU-8 or derivative, a poly(p-xylylene) or derivative.

In some embodiments, disclosed is an electrical interconnect patterning process which incorporates a radiation tolerant dielectric and metallization for electrical interconnect. In some aspects, the Bump Metal can be deposited using evaporation. The Bump Metal can be Indium or other suitable interconnect material.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

The term “substantially” is meant to permit deviations from the descriptive term that don't negatively impact the intended purpose. Descriptive terms are implicitly understood to be modified by the word substantially, even if the term is not explicitly modified by the word substantially.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. The term “about” can include traditional rounding according to significant figures of numerical values. In addition, the phrase “about ‘x’ to ‘y’” includes “about ‘x’ to about y”.

Therefore, at least the following is claimed:

1. A process, comprising:
disposing a radiation hard dielectric layer on a substrate, the radiation hard dielectric layer comprising a dielectric that maintains defined dielectric properties when exposed to at least 50 mrads of proton radiation or at least 4×10¹⁵ of 1 MeV equivalent neutron radiation;
patterning the radiation hard dielectric layer; and
treating the radiation hard dielectric layer.

2. The process of claim 1, wherein the dielectric maintains at least a dielectric strength of 100V/micron when exposed to at least 50 mrads of proton radiation or at least 4×10¹⁵ of 1 MeV equivalent neutron radiation.

3. The process of claim 1, wherein treating the radiation hard dielectric layer comprises curing the radiation hard dielectric layer.

4. The process of claim 1, further comprising forming and patterning one or more photoresist layer on the radiation hard dielectric layer.

5. The process of claim 4, further comprising:
disposing bump metal on the one or more photoresist layer and in patterned openings of the radiation hard dielectric layer; and
removing the one or more photoresist layer and the bump metal on the one or more photoresist layer.

6. The process of claim 1, wherein the radiation hard dielectric layer is disposed on the substrate by spin coating.

7. The process of claim 1, wherein the radiation hard dielectric layer is treated using thermal, chemical or plasma based processing.

8. The process of claim 1, wherein a first photoresist layer is formed on the radiation hard dielectric layer, and a second photoresist layer is formed on the first photoresist layer.

9. The process of claim 1, wherein the bump metal is deposited using evaporation.

10. The process of claim 1, wherein the bump metal is indium.

11. The process of claim 1, wherein the radiation hard dielectric layer comprises a polyimide, a benzocyclobutene, an SU-8, a poly(p-xylylene) or derivatives thereof.

12. A device, comprising:
a substrate; and
a patterned radiation hard dielectric layer disposed on the substrate, the radiation hard dielectric layer comprising a dielectric that maintains defined dielectric properties when exposed to at least 50 mrads of proton radiation or at least 4×10¹⁵ of 1 MeV equivalent neutron radiation.

13. The device of claim 12, wherein the patterned dielectric maintains at least a dielectric strength of 100V/micron when exposed to at least 50 mrads of proton radiation or at least 4×10¹⁵ of 1 MeV equivalent neutron radiation.

14. The device of claim 12, where the patterned radiation hard dielectric layer comprises openings extending through the radiation hard dielectric layer.

15. The device of claim 14, further comprising bump metal disposed in the openings of the patterned radiation hard dielectric layer.

16. The device of claim 15, where the bump metal does not overlap the patterned radiation hard dielectric layer.

17. The device of claim 15, wherein the bump metal is disposed on the substrate.
